(19) United States
(12) Patent Application Publication
(10) Pub. No.: US 2009/0033401 A1
(43) Pub. Date: Feb. 5, 2009

(54) Level Shifting Circuit With Symmetrical Topology

(75) Inventors: Marcel A. Kossel, Reichenburg (CH); Hayden C. Cranford, Cary, NC (US)

Correspondence Address: IBM CORPORATION, PO BOX 12195, DEPT YXSA, BLDG 002, RESEARCH TRIANGLE PARK, NC, 27709, US

(73) Assignee: INTERNATIONAL BUSINESS MACHINES (IBM), Armonk, NY (US)

(21) Appl. No.: 11/832,699

(22) Filed: Aug. 2, 2007

(51) Int. Cl. H03L 5/00

(52) U.S. Cl. 327/333

(57) ABSTRACT

A shifter circuit includes a pair of feed forward sections and a pair of feedback sections. The sections are arranged and coupled to form a balanced symmetrical topology. The feed forward sections each include inverter pairs of PMOS and NMOS devices. The feedback sections each include a pair of cross-coupled devices. A pair of output nodes are operatively positioned between the pair of feedback sections. A method for using the circuit to generate output signals at respective output ports is also disclosed.

### BACKGROUND OF THE INVENTION

1. Technical Field

The present invention relates to electronic circuits in general and particularly to the type of circuits known as level shifters implemented in solid state technology.

2. Description of Related Art

Level shifting circuits, sometimes referred to as the level shifters fabricated with solid state technology, are well known in the prior art. All of these circuits provide the same results: namely, converting an input signal from a first level to a second level. As a consequence the differences between the circuits are generally based upon different circuit topology and the way in which the particular circuit topology works to shift the signal from one level to the next.

FIG. 1 is a typical prior art shifting circuit extracted from U.S. Pat. No. 6,407,579. It consists of a thin oxide inverter 108 and a cross-coupled pair of thick oxide PMOS transistors 102, 104 that are connected to two thick oxide NMOS transistors 106 and 110. The input signal labeled “in” and the inverted input signal labeled “inb” are applied to the gate of NMOS transistors 106 and 110. This signal path can be regarded as the feed forward path that pulls down the output labeled “out” to ground if the input signal is low. The cross-coupled transistor pair 102, 104 acts in this case, as feedback paths that pulls up the other output terminal labeled “outb” to the high voltage supply. The transistors 102, 104 can only switch after the input signal has propagated through the feed forward path. Therefore, the cross-coupled devices 102 and 104 form the feedback path.

Still referring to FIG. 1, this classical level shifting circuit and others like it work well for static or low speed application. However, at higher speeds two drawbacks become clearly visible. First the inverter delay together with the delay through the feedback path limit the speed of operation. Secondly, and even more important, the strength of the feedback path becomes too weak at higher frequencies. As a consequence, unequal rise and fall times might occur because the cross-coupled devices cannot pull up the output node fast enough. An increase of the driver strength by using bigger transistors (an obvious solution) does not solve the problem since too much pre-drive power would then be required. The rationale behind the weakness of the cross-coupled PMOS devices 102, 104 is given by the fact that their widths have to be chosen smaller than the widths of the NMOS transistors 106 and 110 in order to perform the required level-shifting operation, which can also be regarded as converting the input referred switching point to the switching point of the level-shifted output signals. Because the output referred switching point is typically higher than the one at the input, the transistor widths of the PMOS transistors 102, 104 have be chosen smaller than the widths of the NMOS transistors 106, 110 such that the desired conversion of the different signal switching points can be performed.

As describe above the distinguishing features between different shifting circuits is based upon different circuit topologies. Usually, the topology includes thin oxide and thick oxide devices. In order to protect the thin oxide devices additional protective circuits are required. Without the protective circuits breakdown of the gate oxide could occur. The protective circuits require additional silicon area on the chip. It is well known in silicon logic technology, that silicon real-estate is at a premium. Therefore, limiting the size of the protective circuits or eliminating them altogether would free-up silicon area in which additional circuits could be placed. As a consequence, it is desirable to provide a shifter circuit in which the protective circuit is absent.

In view of the above, there is a need for a shifter circuit suitable for use in high speed data transmission application and does not require protective circuit to protect thin oxide devices. The invention to be described hereinafter provides a shifter circuit which circumvent the drawbacks of the prior art.

### SUMMARY OF THE INVENTION

The present invention avoids the shortcomings of the prior art by providing a level shifting circuit with balance and symmetrical feed forward and feedback signal paths. The feed forward signal path includes two inverter pairs (202, 210) and (208, 216). The feedback signal path includes two pairs of cross-coupled devices 204, 206 and 212, 214. The named devices are operatively coupled to form a symmetrical balance structure.

### BRIEF DESCRIPTION OF THE DRAWINGS

A better understanding of the present invention can be obtained when the following detailed description is considered in conjunction with the following drawings, in which:

FIG. 1 is a schematic of the related art shifter circuit described in the related art section of this document.

FIG. 2 is a schematic of the shifter circuit according to teachings of the present invention.

FIG. 3 is a graphical representation of an input clock and simulated signal curves generated by the prior art shifter circuit (FIG. 1) and the shifter circuit of the present invention.

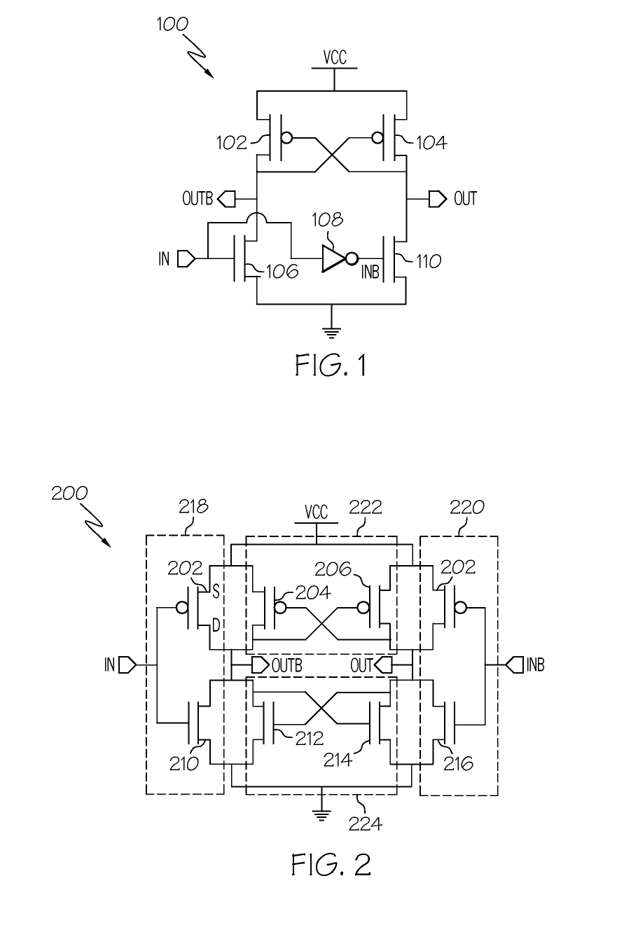

### DETAILED DESCRIPTION OF THE INVENTION

FIG. 2 shows a circuit schematic of the shifter circuit according to teachings of the present invention. The shifter circuit 200 includes a first feed forward section 218, a second feed forward section 220, a first feedback section 222 and a second feedback section 224. The named sections are connected to form a balanced and symmetrical circuit topology. A supply voltage Vcc is connected to the first feedback section 222 and provides power to the circuit.

Still referring to FIG. 2, the first feed forward section 218 includes devices 202 and 210 that function or operate as an inverter pair. In the preferred embodiment of this invention device 202 is a PMOS device and 210 is an NMOS device. A node labeled “in” is connected to the PMOS and NMOS devices and provide the input terminal to which the input signal, to be shifted through the circuit, is applied. Likewise, second feed forward section 220 is positioned in spaced and symmetrical relationship to the first feed forward section. The second feed forward section 220 includes devices 208 and 216. As with the first feed forward section the second feed forward section functions as an inverter pair. In the preferred embodiment of the present invention device 208 is a PMOS device and device 216 is an NMOS device. A terminal labeled “inb” is connected to PMOS device 208 and NMOS device to 216. The terminal “inb” provides an input port to which a controlled signal is applied to pull-up or pull-down node “out” independent of the effect of the cross coupled sections on node “out”.

Referring to FIG. 2 again, the feedback section 222 is operatively coupled to feed forward sections 218 and 220, respectively. The feedback section 222 includes cross-coupled devices 204 and 206. In the preferred embodiment of this invention device 206 is a PMOS device and device 204 is a PMOS device. The second feedback section 224 is operatively coupled in spaced and symmetrical relationship to the first feedback section. The second feedback section includes cross-coupled devices 212 and 214. In the preferred embodiment of the invention device 212 is NMOS and device 214 is also NMOS. The second feedback section is also operatively coupled to the feed forward sections 218 and 220 respectively. A first output terminal labeled “outb” and a second output terminal labeled “out” are operatively connected between the first feedback section 222 and second feedback section 224. Based upon the description and FIG. 2, it is clear that the shifter of the present invention is symmetrical and balanced. As a consequence the output signals generated by the shifter circuit of the present invention is also symmetrical and balanced.

Before describing the operation of the shifter circuit of the present invention some observation of its virtues is worth while noting. The cross coupled transistors 204, 206 and 212, 214 are responsible for pulling-up or pulling-down the output to the ground potential or the high voltage level while the feed forward transistors 202, 210 and 208, 216 bias the output nodes such that the strength of the cross coupled devices is still strong enough even at very high data rates. As a consequence the voltage of the output node gets already moved into the right direction by the feed forward path even before the switching through the feedback path comes into play. The biasing through the feed forward path help keep the dimension of the cross coupled transistors small compared to the prior art level shifter. The PMOS devices of the level shifter of the present invention are preferentially implemented as high voltage transistor (HVT) devices in order to make sure that the transistors 202 and 208 are completely turned off when the input signal is logically high. Ideally, the threshold voltage for each of devices 202 and 208 should be equal or greater than the voltage difference between the two voltage domains. If thick oxide transistors are not available as high voltage transistor devices, the threshold voltage of 202 and 208 can also be increased by an appropriate control of their body voltage. The threshold voltage of PMOS transistors increases with increasing body voltage.

Having described the structure of the shifter circuit according to teachings of the present invention, its operation will now be described with reference to the topology set forth in FIG. 2. First the description will address the operation when the input signal on input port labeled “in” is high, say 1.0 V followed by the description when the input signal is low say zero volt. Because the signal is at 1.0 volt the PMOS transistor 202 turns off and the NMOS transistor 210 turns on. As a consequence, the output on terminal “outb” is pulled down to 0 volt. The more “outb” gets to ground the more the cross-coupled PMOS transistor 206 turns on and pulls the output “out” towards Vcc which corresponds in this case to the level-shifted high voltage (e.g. 1.5V). In contrast to prior art level shifters the level shifter of the present invention has only one voltage supply which eases the physical design (layout) so that less silicon area needs to be consumed.

Still describing the operation of the shifter circuit according to teachings of the present invention, when input signal on terminal “in” is low, say 0 volts NMOS 210 turns off and PMOS 202 turns on pulling up output node “outb” to Vcc which in this case is 1.5 volts. With node “outb” rising from 0 volts to 1.5 volts, NMOS 214 turns on pulling node “out” to ground.

With respect to FIG. 2 circuit schematic, the propagation of the input signal “in” from left to right has been discussed. First the transistor 210 needs to turn on so that afterwards transistor 206 can turn on, too. Because of this concatenation of signal transitions, the cross-coupled transistors form a feedback path since they can only switch after the corresponding output terminal connected to their gate node has changed its logical state. The problem of this configuration which corresponds so far to the operation of the reference prior art level shifter is that the cross-coupled PMOS transistor is typically too weak to pull up the output node “out” at very high speeds. This weakness is caused by the different transistor sizing of the PMOS and NMOS devices in the level shifter. In contrast to, for instance, a regular inverter where the PMOS transistor is typically twice as wide as the NMOS transistor because of the half as high electron mobility of the PMOS devices, the sizing of the transistors in a level-shifter also reflects the unsymmetrical switching points and does not only account for the different electron mobility.

Typically the input referred switching point of the level shifter is at a lower voltage than the switching point of the output. In terms of transistor dimensioning, this means that the NMOS devices have to be chosen larger than the PMOS devices in order to shift the switching points towards higher voltages. Because of the larger dimension of the NMOS devices and the feedback configuration of the cross coupled devices, as explained above, the-low-to-high transition at the cross coupled PMOS transistors is a weak point in the prior art level shifter and finally limits the speed of operation of the whole level shifting circuit. The present invention provides an additional feed forward path in parallel to the cross-coupled PMOS devices that help increase the drain potential of 204 and 206 so that they do not need to pull up the output node “out” all the way from ground to Vcc but instead only need to pull-up “out” starting from a higher voltage (for example 60% of Vcc). This significantly increases the speed of the whole circuit and also allows getting more symmetrical waveforms in terms of rise and fall times.

Stated another way the feed forward devices in the feed forward section of the present invention pre-charge the output node “out” and the cross-coupled devices finally charge the output node “out” to a predefined voltage level. As used in this document feed forward devices are devices which are activated or turned-on directly by signals external to the shifter circuit. The feed forward devices are placed in parallel with cross-coupled devices. With reference to FIG. 2 for the moment, PMOS device 208 is in parallel with cross-coupled PMOS 206 and is activated by control signal “inb”, generated external to the shifter circuit. In the preferred embodiment of this invention PMOS 208 is controlled directly by “inb” which is out of phase with respect to input signal “in”. By providing feed forward devices which can be activated directly by external signals the nodes, such as “out” and “outb”, to which they are connected can be pre-charge (partially charged) or fully charged without assistance from the cross-coupled devices.

As mentioned above the shifter circuit according to teachings of the present invention requires only a single power supply. A single dc power supply could have an impact on the feed forward PMOS transistors 202 and 206. For instance, during low-to-high transition it is assumed that PMOS 202 is switched off completely when the input signal “in” has reached 1 (one) volt (V). The source potential of PMOS 202 is however, at 1.5 V and the drain potential is around 0 V. In order to prevent any leakage current flowing through 202, one as to make sure that 202 is completely switched off when the gate potential of 202 is at 1 V. If PMOS transistors with a High Voltage Threshold (HVT) implant are available, this is an easy task as long as the threshold is higher than the difference between the output high voltage and input high voltage (in this case 0.5 V). If such HTV transistors are not available then the voltage threshold can be provided by increasing the bulk potential of the PMOS transistors 202 and 206 to a higher voltage. The magnitude of the threshold voltage increases if the source-bulk junction is increasingly reverse-biased. Typically the bulk potential of PMOS transistors is tied to the highest potential of the circuit—in this case to Vcc. A further increase of that bulk potential to a voltage higher than Vcc would additionally increase the threshold voltage of the PMOS devices because their source-bulk junction becomes even more reverse-biased. As long as no reverse breakdown occurs the threshold voltage gets higher with increasing bulk potential. In a practical circuit implementation of the level shifter, it might be feasible that the level shifter is operated under a regulated supply, where Vcc would then be the regulated dc supply of the circuit. In such a case, the bulk potential might for instance be tied to the supply voltage of the regulator itself, which might be a few hundred millivolts higher than Vcc and hence the threshold voltage of the PMOS transistors gets significantly increased. If no such supply regulator is available, the higher bulk potential could also be generated by a voltage pump that produces out of Vcc a slightly higher positive voltage.

This will increase the PMOS transistors' threshold voltage such that the above conditions is fulfilled and 202, 206 are completely turned off.

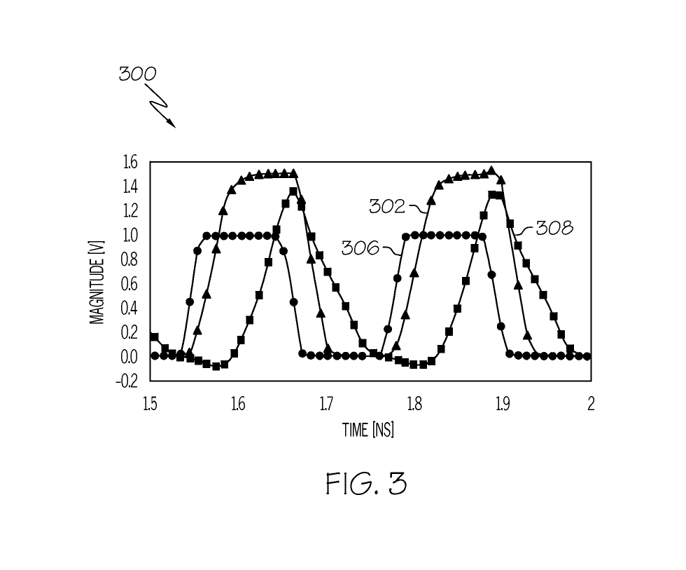

FIG. 3 shows a graphical representation 300 of simulated output signals 302 and 308. The simulated output signal 302 is generated from the shifter according to the teachings of the present invention. The simulated output signal 308 represents output signal generated by the shifter of the prior art. The input clock signal 308 is a 1 volt clock signal at 4.25 gigahertz (GHz) which represents the target clock frequency of a half rate 8.5 Gb/s transmitter. In the figure, time in nanosecond is represented on the horizontal axis while magnitude in units of volts is represented on the vertical axis. The graph is helpful in understanding the present invention and the superiority of the shifter circuit according to teachings of the present invention. As is evident by comparison between graphs 302 and 308, 302 outperform graph 308 in every respect. In particular, while the level shifter according to the teachings of the present invention perform the level shifting pretty well, the prior art level shifter fails because of the above mentioned conditions related to the delay and the driver strength issues. To enable a fair comparison, the device sizes of the two level shifters and thus their overall area are comparable to each other in this example.

While the present invention and its advantages have been described in detail, it should be understood that various changes, substitution and alterations can be made without departing from the spirit and scope of the present invention as defined by the following claims.

What is claimed is:

1. A method comprising:
providing a shifter circuit;
pre-charging, to a first voltage level, an output node of said circuit with a switching device activated by a control signal generated from a source external to the shifter circuit; and
charging to a pre-defined voltage level, said output node with a switching device activated by a signal propagated within said shifter circuit.

2. The method of claim 1, further including charging a second output node to a second pre-defined voltage level with a device activated by an input signal.

3. The method of claim 2, further including selecting in phase pulses of a clock signal as the input signal.

4. The method of claim 1 further including selecting out-of-phase pulses of a clock signal as the control signal.

5. A shifter circuit comprising:
a first output node;
a feed forward circuit operatively coupled to said first output node, said feed forward circuit pre-charging said first output node to a pre-charge voltage level; and
a feedback circuit, operatively coupled to said first output node, for charging said first output node to a predefined final voltage level.

6. The shifter circuit of claim 5, further including a second output node; and
a second feed forward circuit, operatively coupled to said second output node, for charging said second output node to a predefined final voltage level.

7. The shifter circuit of claim 5 wherein the first feed forward circuit includes
an inverter pair of devices connected in series; and
an input node for receiving an input signal operatively connected to the inverter pair.

8. The shifter circuit of claim 7 wherein the inverter pair includes a PMOS device and an NMOS device.

9. The shifter circuit of claim 5 wherein the feedback circuit includes two pairs of cross-coupled transistor pair devices.

10. The shifter of claim 9 wherein a first pair of the cross-coupled transistor pairs device includes a first pair of PMOS devices.

11. The shifter circuit of claim 10 wherein a second pair of the cross-coupled transistor pairs devices include a second pair of NMOS devices.

12. A shifter circuit comprising:
A first feed forward section;
a second feed forward section displaced from and symmetrically positioned relative to said first feed forward section;
a first feedback section operatively coupled to said first feed forward section and said second feed forward section; and
a second feedback section displaced from and symmetrically placed relative to said first feedback section wherein said second feedback section is operatively coupled to the first feed forward section, the second feed forward section and the first feedback section.

13. The shifter circuit of claim 12 further including a first output node (outb) operatively coupled to the first feed forward section; and
a second output node (out) operatively coupled to the second feed forward section.

14. The shifter circuit of claim 12 further including a first input node (in) for receiving an input signal operatively coupled to the first feed forward section; and
a second input node (inb) for receiving a control signal operatively coupled to said second feed forward section.

15. The shifter circuit of claim 12 wherein the first feed forward section includes an inverter pair.

16. The shifter circuit of claim 15 wherein the inverter pair includes a PMOS device connected in series to an NMOS device.

17. The shifter circuit of claim 12 wherein the second feed forward section includes an inverter pair.

18. The shifter circuit of claim 17 wherein the inverter pair includes a PMOS device connected in series to an NMOS device.

19. The shifter circuit of claim 12 wherein the first feedback section includes a pair of cross-coupled devices.

20. The shifter circuit of claim 19 wherein the pair of cross-coupled devices includes a pair of PMOS devices.

21. The shifter circuit of claim 12 wherein the second feedback section includes a pair of cross-coupled devices.

22. The shifter circuit of claim 21 wherein the pair of cross-coupled devices includes NMOS devices.

23. The shifter circuit of claim 12 further including a single power supply operatively coupled to the first feedback section and the second feedback section.
